(19) United States
(12) Patent Application Publication
(10) Pub. No.: US 2005/0155555 A1
(43) Pub. Date: Jul. 21, 2005

(54) Semiconductor manufacturing apparatus

(76) Inventors: Kyu-hee Han, Kunpo-si (KR); Ju-hyun Lee, Suwon-si (KR); Hee-jeon Yang, Kunpo-si (KR); Ki-hyun Kim, Yongin-si (KR)

Correspondence Address: STANZIONE & KIM, LLP, 1740 N STREET, N.W., FIRST FLOOR, WASHINGTON, DC, 20036, US

(21) Appl. No.: 11/020,006

(22) Filed: Dec. 23, 2004

(30) Foreign Application Priority Data
Dec. 26, 2003 (JP) 2003-97591

(51) Int. Cl. C23C 16/00

(52) U.S. Cl. 118/723 I; 118/724; 156/345.27

(57) ABSTRACT

A semiconductor manufacturing apparatus includes a chamber main body and a dome to form an accommodating space to accommodate a substrate, an antenna provided on the dome to generate a plasma in the accommodating space, and a temperature controller provided on the dome to control a temperature of the dome. The temperature controller includes a heat transfer unit provided on the dome or in the vicinity of the dome and the antenna, a heater provided on the heat transfer unit to heat the dome, a cooler provided between the heat transfer unit and the heater to cool the dome, and an adjusting valve connected to the cooler to adjust the quantity of coolant supplied to the cooler to control the temperature of the dome within a predetermined reference temperature range. The temperature of the dome may be maintained constant within the predetermined reference temperature range if an electrical power with a high voltage is supplied to the antennato generate the plasma with a high density in the chamber.

### CROSS-REFERENCE TO RELATED APPLICATIONS

This application claims the benefit of Korean Patent Application No. 2003-97591, filed Dec. 26, 2003, in the Korean Intellectual Property Office, the disclosure of which is incorporated herein by reference.

### BACKGROUND OF THE INVENTION

1. Field of the Invention

The present invention relates to a semiconductor manufacturing apparatus, and more particularly, to a semiconductor manufacturing apparatus comprising a temperature controller having an improved structure to control the temperature of a dome provided in a chemical vapor deposition (CVD) chamber with a high density plasma.

2. Description of the Related Art

Generally, in semiconductor manufacturing equipment, a chamber for a semiconductor manufacturing process comprises a chamber main body and a dome forming an accommodating space to accommodate mainly one or more wafers, a gas supply device having gas injecting nozzles to supply a deposition gas to the chamber, and a substrate supporter provided in the chamber to support the wafers. The dome is provided on the chamber main body and forms the accommodating space together with the chamber main body to accommodate and deposit the wafers. On the dome are provided an antenna to which a radio frequency (RF) power is supplied to excite the deposition gas supplied to an inside of the chamber into a plasma state, and a temperature controller to control a temperature of the dome heated by the plasma.

Recently, a wafer with a higher capacity has been required, which causes demands for a wafer having a pattern with a higher density. To deposit the wafer having the pattern with the higher density, electrical power with a high voltage should be supplied to the antenna. Then, a plasma with a high temperature and a high density is formed, which enables to deposit the wafer having the pattern with the higher density.

The dome is usually made of a ceramic material. To protect the dome of the ceramic material against a thermal shock, the dome should keep at a constant temperature.

U.S. Pat. No. 6,286,451, entitled “dome: shape and temperature controlled surfaces,” discloses a temperature controller that is provided in a dome of semiconductor manufacturing equipment. A temperature controller that is provided in conventional semiconductor manufacturing equipment will be described with reference to FIG. 1. Referring to FIG. 1, a coil 72 is provided on a dome (not shown) as an antenna, and a temperature control assembly 64 is provided on the coil 72.

The temperature control assembly 64 comprises a heat transmitting plate 86 provided on the coil 72, a heating plate 80 provided on the heat transmitting plate 86 to increase the temperature of the dome to a predetermined reference temperature, and a cooling plate 82 provided on the heating plate 80 to cool the dome. Between adjacent plates 80, 82, and 86 are provided heat transfer layers 90, 88 and 84, respectively.

The cooing plate 82 comprises a cooling water channel to pass cooling water therethrough.

In the temperature control unit of the conventional semiconductor manufacturing equipment, the dome is cooled by continuously circulating the cooling water through the cooling water channel of the cooling plate 82, while plasma is formed in the chamber.

However, in the temperature control unit of the conventional semiconductor manufacturing equipment, the cooling plate 82 is provided only on the heating plate 80, thereby causing a problem that the dome is not sufficiently cooled if the dome is heated to a high temperature when the electric power with high-voltage is supplied to the coil 72 to deposit the wafer with the high-capacity.

### SUMMARY OF THE INVENTION

Accordingly, it is an aspect of the present invention to provide a semiconductor manufacturing apparatus with a temperature controller to maintain the temperature of a dome constant if an electrical power with a high-voltage is supplied to an antenna.

Additional aspects and/or advantages of the invention will be set forth in part in the description which follows and, in part, will be obvious from the description, or may be learned by practice of the invention.

The foregoing and/or other aspects of the present invention are achieved by providing a semiconductor manufacturing apparatus comprising: a chamber main body and a dome to form an accommodating space to accommodate one or more substrates; an antenna provided on the dome to generate plasma in the accommodating space; and a temperature controller provided on the dome to control the temperature of the dome. The temperature controller comprises: a heat transfer unit provided on the dome or in the vicinity of the dome and the antenna; a heater provided on the heat transfer unit to heat the dome; a cooler provided between the heat transfer unit and the heater to cool the dome; and an adjusting valve connected to the cooler to adjust the quantity of coolant supplied to the cooler to control the temperature of the dome within a predetermined reference temperature range.

According to an aspect of the invention, the cooler comprises a coolant channel as a passage of the coolant, a supply pipe provided at an entrance of the coolant channel and a discharge pipe provided at an exit of the coolant channel, and the adjusting valve is provided at at least one of the supply pipe and the discharge pipe.

According to another aspect of the invention, the temperature controller further comprises a temperature sensor to sense the temperature of the dome. The adjusting valve is closed when the temperature of the dome, sensed by the temperature sensor, is equal to or less than the predetermined reference temperature range, and is opened when the temperature of the dome is above the predetermined reference temperature range.

According to yet another aspect of the invention, the predetermined reference temperature range is between approximately −20° C. through +20° C. to a set reference temperature of the dome.

According to still another aspect of the invention, the adjusting valve can be controlled according to an electrical power supplied to the antenna.

According to yet another aspect of the invention, the semiconductor manufacturing apparatus may further include an upper cover on the heater.

According to yet another aspect of the invention, the temperature controller may further include an auxiliary cooler provided on the heater to cool the dome.

According to yet another aspect of the invention, the auxiliary cooler may include an auxiliary coolant channel as a passage of the coolant, an auxiliary supply pipe provided at an entrance of the auxiliary coolant channel and an auxiliary discharge pipe provided at an exit of the auxiliary coolant channel.

According to still another aspect of the invention, the temperature controller may further include an auxiliary adjusting valve provided at at least one of the auxiliary supply pipe and the auxiliary discharge pipe to adjust the quantity of the coolant supplied to the auxiliary coolant channel.

According to still another aspect of the invention, the auxiliary adjusting valve can be controlled according to the temperature of the dome.

According to yet another aspect of the invention, the auxiliary adjusting valve can be controlled according to an electrical power supplied to the antenna.

According to still another aspect of the invention, the auxiliary temperature controller may further include a cover provided on the auxiliary cooler to prevent the coolant from leaking from the coolant channel.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a partial perspective view of conventional semiconductor manufacturing equipment;

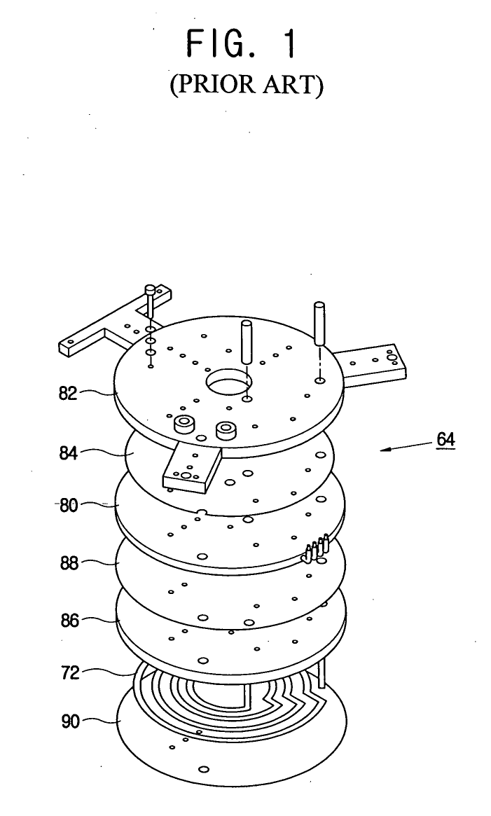

FIG. 2 is a partial schematic view of a semiconductor manufacturing apparatus according to an embodiment of the present invention;

FIG. 3 is a sectional view of a temperature controller of the semiconductor manufacturing apparatus iillustrated n FIG. 2;

FIG. 4 is an exploded perspective view of the temperature controller illustrated in FIG. 3; and

FIG. 5 is a partial schematic view of a semiconductor manufacturing apparatus according to another embodiment of the present invention.

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

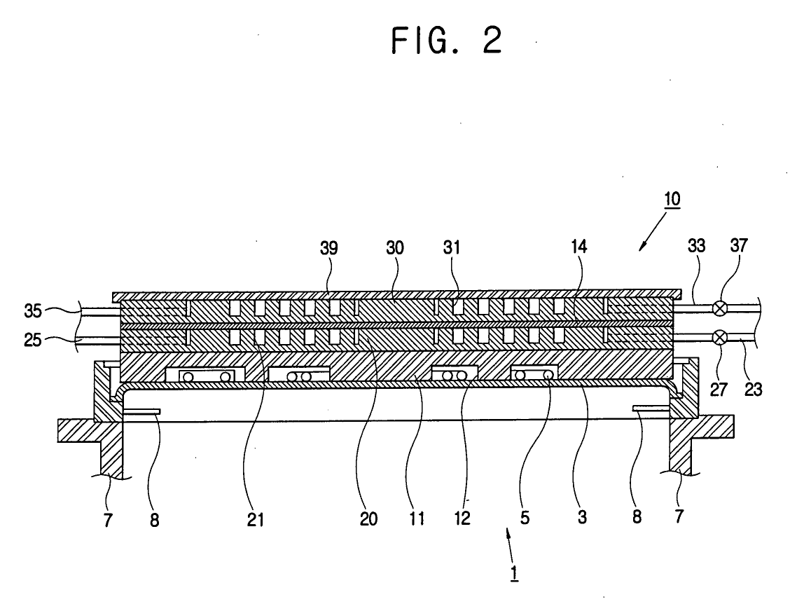

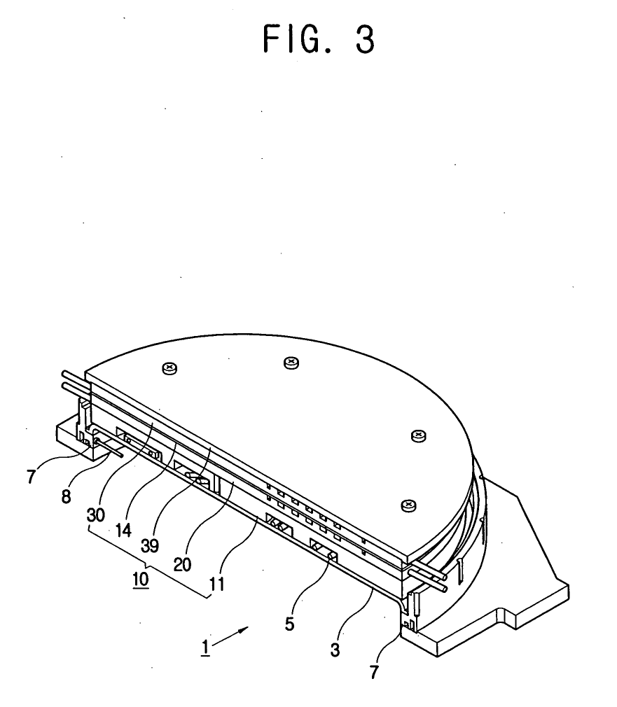

As shown in FIGS. 2 through 4, a semiconductor manufacturing apparatus according to an embodiment of the present invention includes a chamber 1 to perform a deposition on at least one substrate (not shown) such as at least one wafer for a semiconductor manufacturing process.

The chamber 1 includes a chamber main body 7 and a dome 3 to form an accommodating space to accommodate the substrate, a gas supply device (not shown) having gas injecting nozzles 8 to supply a deposition gas to the chamber 1, a substrate supporter (not shown) provided in the chamber 1 to support the substrate, an antenna 5 provided on the dome 3 to supply a radio frequency (RF) power to excite the deposition gas supplied to an inside of the chamber 1 into a plasma state, and a temperature controller 10 to control the temperature of the dome 3 heated by the plasma.

The chamber main body 7 may have a cylinder shape having a closed bottom to accommodate the substrate supporter. The chamber main body 7 may include a substrate entrance (not shown) through which the substrate enters/exits the chamber main body 7, a vacuum pump (not shown) to make the inside of the chamber 1 vacuum and a gas discharge part (not shown) to discharge the deposition gas after the deposition is completed.

The gas injecting nozzles 8 are provided in plural on an inner surface of the chamber main body 7 to eject the deposition gas to the inside of the chamber 1.

The dome 3 is provided on the chamber main body 7 and is connected to the chamber main body 7 by a fastener, such as a screw 40, to form the accommodating space together with the chamber main body 7 to accommodate and deposit the substrate. The dome 3 may be made of a ceramic material to maintain a constant temperature so that the dome 3, which may be made of the ceramic material, is protected against a thermal shock. The dome 3 may have a disk shape corresponding to a shape of the chamber main body 7. The dome 3 may be made of a ceramic material, such as Al₂O₃, but is not limited thereto. Another type of a ceramic that the dome 3 may be made of is, for example, ALN or SiO₂.

The antenna 5 may be provided on the dome 3 and have a coil shape. The electrical power with a high voltage may be supplied to the antenna 5 to perform the deposition on a high-capacity substrate having a high-density pattern. If the electrical power with the high voltage is supplied to the antenna 5, a plasma with a high temperature and a high density is formed in the chamber 1 to enable the deposition on the substrate having the pattern with the high density. The electrical power supplied to the antenna 5 may be approximately 5000W, but is not limited thereto. The power supplied to the antenna 5 may be 1000W through 2000W.

The temperature controller 10 includes a heat transfer unit 11 provided on the dome 3 or in the vicinity of the dome 3 and the antenna 5, a heater 14 provided on the heat transfer unit 11 to heat the dome 3, a cooler 3 provided between the heat transfer unit 11 and the heater 14 to cool the dome 3, and an adjusting valve 27 connected to the cooler 20 to adjust the quantity of coolant supplied to the cooler 20 and to control the temperature of the dome 3 in a predetermined reference temperature range. In an aspect of the present invention, the temperature controller 10 may further include an auxiliary cooler 30 provided on the heater 14 to cool the dome 3. In another aspect of the present invention, the temperature controller 10 may further include a temperature sensor (not shown) provided an outside or inside of the dome 3 to sense the temperature of the dome 3.

The heat transfer unit 11 can be made of a material having high thermal conductivity to conduct heat between the cooler 20 and the dome 3. In an aspect of the present invention, the heat transfer unit 11 may have a disk shape corresponding to a shape of the dome 3. At a lower part of the heat transfer unit 11 is provided an antenna accommodating part 12 to accommodate the antenna 5.

The heater 14 may have a disk shape corresponding to the shape of the cooler 20. The heater 14 is provided to increase the temperature of the dome 3 to the predetermined reference temperature range. When the chamber 1 is initially operated, the dome 3 is at the normal temperature. Thus, the heater 14 heats the dome 3 at the normal temperature to increase the temperature of the dome 3 to a reference temperature, which helps to generate the plasma. Due to the plasma with the high density, the temperature of dome 3 rapidly rises, thereby protecting the dome 3 against a thermal shock. The reference temperature of the dome 3 may be variously set according to the electrical power supplied to the antenna 5, the deposition gas, the substrate and the like. The predetermined reference temperature range of the dome 3 may be in a range between +20° C.˜−20° C. of the reference temperature. For example, if the reference temperature of the dome 3 is set as 100° C., the predetermined reference temperature range may be 80° C. through 120° C. The predetermined reference temperature range of the dome 3 may be also in a range between +10° C.˜−10° C. of the reference temperature. The reference temperature range of the dome 3 may be greater than the reference temperature set in the dome becomes higher. That is, if the reference temperature of the predetermined reference temperature range of the dome 3 is higher than 100° C., the reference temperature range may be in a range between 80%˜130% of the reference temperature.

In an aspect of the present invention, the cooler 20 may have a disk shape corresponding to the shape of the heat transfer unit 11. The cooler 20 may include a coolant channel 21 to provide a passage of the coolant, a supply pipe 23 provided at an entrance of the coolant channel 21 and a discharge pipe 25 provided at an exit of the coolant channel 21.

The coolant channel 21 may include one or more grooves with arc shapes connected to one another on an upper surface of the cooler 20. The coolant channel 21 may be in close contact with the heater 14 provided on the cooler 20 to prevent a leakage of the coolant. Further, a cooler cover may be provided between the cooler 20 and the heater 14 and may be in close contact with the cooler 20 to prevent the leakage of the coolant from the coolant channel 21. The coolant may be in a fluid state, such as cooling water, to be supplied to the coolant channel 21.

The supply pipe 23 has a first side connected to a coolant storage (not shown) and a second side connected to the coolant channel 21. The coolant storage may be able to control a temperature of the coolant according to the reference temperature of the dome 3. For example, the coolant storage may include a cooling device (not shown) and a heating device (not shown) to control the temperature of the coolant in a range of −30° C.˜160° C. according to the reference temperature of the dome 3. The discharge pipe 25 may have a first side connected to the coolant channel 21 and a second side connected to the coolant storage. Thus, the coolant is supplied from the coolant storage through the supply pipe 25 to the coolant channel 21. The coolant passing through the coolant channel 21 may be discharged through the discharge pipe 25 to the coolant storage.

The adjusting valve 27 may be at one of the supply pipe 23 and the discharge pipe 25. According to this embodiment of the present invention, the adjusting valve 27 is provided at the supplying valve 23. The adjusting valve 27 may be a flux adjusting valve to adjust the quantity of the coolant passing through the supplying valve 24. The adjusting valve 27 may be simply a switch to open/close the supplying valve 23. The adjusting valve 27 may be closed if the temperature of the dome 3, sensed by the temperature sensor, is below the predetermined reference temperature range and opened if the temperature of the dome 3, sensed by the temperature sensor, is above the predetermined reference temperature range.

The adjusting valve 27 may be adjusted according to the electrical power supplied to the antenna 5. That is, the density of the plasma in the chamber 1 is changed according to the electrical power supplied to the antenna 5, which changes the temperature of the dome 3. For example, as the electrical power supplied to the antenna increases, the density of the plasma in the chamber 1 becomes higher to increase the temperature of the dome 3. Thus, the adjusting valve 27 may be adjusted such that more coolant is supplied to the cooler 20.

The auxiliary cooler 30 includes an auxiliary coolant channel 31 to provide a passage of the coolant, an auxiliary supply pipe 33 provided at an entrance of the coolant channel 31 and an auxiliary discharge pipe 35 provided at an exit of the coolant channel 31. The auxiliary cooler 30 may include an auxiliary adjusting valve 37 provided at one of the auxiliary supply pipe 33 and the auxiliary discharge pipe 35 to adjust the quantity of the coolant supplied to the auxiliary coolant channel 31. A cover 39 may be provided at an upper part of the auxiliary cooler 30 to prevent a leakage of the coolant from the auxiliary coolant channel 31.

A detailed description of the auxiliary coolant channel 31, the auxiliary supply pipe 33 and the auxiliary discharge pipe 35, which are similar to the coolant channel 21, the supply pipe 23 and the discharge pipe 25, respectively, are omitted to avoide repetion and to keep the disclosure brief and concise.

The auxiliary adjusting valve 37 may be similar to the adjusting valve 27. That is, the auxiliary adjusting valve 37 is opened/closed according to the predetermined reference temperature range of the dome 3. The auxiliary adjusting valve 37 may be adjusted according to electrical power supplied to the antenna 5. Further, the auxiliary adjusting valve 37 may be continuously opened to continuously supply the coolant to the auxiliary adjusting valve 37 while the deposition process is performed, without regard to an operation of the adjusting valve 27.

According to a configuration described above, an operation of the temperature controller 10 of the semiconductor manufacturing apparatus according to this embodiment of the present invention will be described hereinafter.

First, the dome 3 at an initial normal temperature is heated by operating the heater 14. Then, the substrate is disposed in the chamber 1 and the deposition gas is injected into the chamber 1 through the gas injecting nozzles 8. The electrical power with the high voltage is supplied to the antenna 5 to generate the plasma with the high density so as to perform the deposition process on the substrate. Here, if the temperature of the dome 3 is below the predetermined reference temperature range, the heater 14 is further operated to increase the temperature of the dome 3. If the temperature of the dome 3 is above the predetermined reference temperature range, the adjusting valve 27 and the auxiliary adjusting valve 37 are opened to circulate the coolant through the adjusting valve 27 and the auxiliary adjusting valve 37, respectively. Then, the temperature of the dome 3 decrease, which enables the temperature of the dome 3 to be maintained within the predetermined reference temperature range. The auxiliary adjusting valve 37 may be continuously opened during the deposition process without regard to the temperature of the dome 3. The adjusting valve 27 and the auxiliary adjusting valve 37 may be adjusted according to the electric power supplied to the antenna 5.

Then, the semiconductor manufacturing apparatus according to this embodiment of the present invention may maintain the temperature of the dome 3 in the predetermined reference temperature range when the electrical power with the high voltage is supplied to the antenna 5 and the plasma with the high density is generated in the chamber 1.

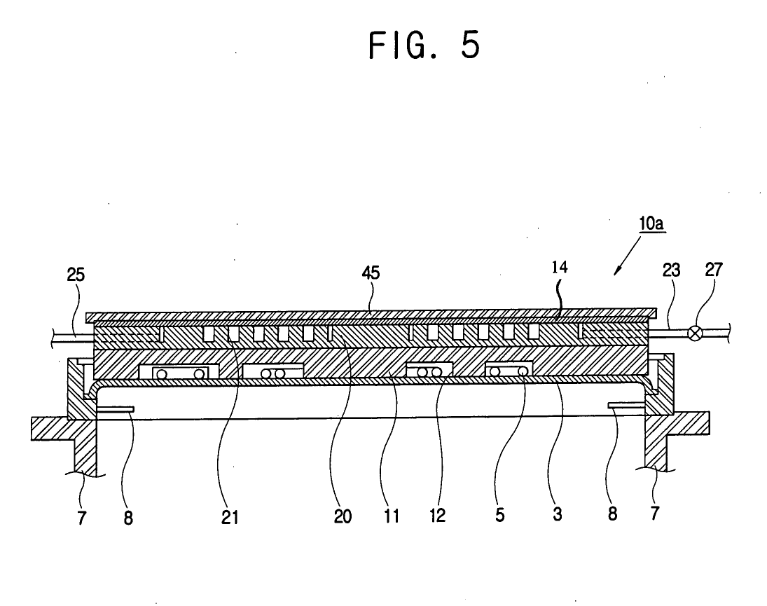

As shown in FIG. 5, a semiconductor manufacturing apparatus according to another embodiment of the present invention does not include an auxiliary cooler and an auxiliary adjusting valve.

The temperature controller 10a of the semiconductor manufacturing equipment according to the embodiment of FIG. 5 include a heat transfer unit 11 provided on the dome 3 and in the vicinity of the dome 3 and the antenna 5, a heater 14 provided on the heat transfer unit 11 to heat the dome 3, a cooler 3 provided between the heat transfer unit 11 and the heater 14 to cool the dome 3, and an adjusting valve 27 connected to the cooler 20 to adjust the quantity of a coolant supplied to the cooler 20 and to keep the temperature of the dome 3 in a predetermined reference temperature range. As an aspect of this embodiment of FIG. 5, the temperature controller 10a may further include an upper cover 45 formed on the heater 14 to prevent a damage of the heater 14.

A detailed description of an operation of the semiconductor manufacturing apparatus according to this embodiment of the present invention will be omitted since it is similar to the operation according to the previous embodiment of the present invention with an exception of the auxiliary cooler 30.

Thus, in the semiconductor manufacturing apparatus according to this embodiment of the present invention, the temperature of the dome 3 may be maintained constant in the predetermined reference temperature range if the electrical power with the high voltage is supplied to the antenna, and the plasma with the high density is generated in the chamber 1.

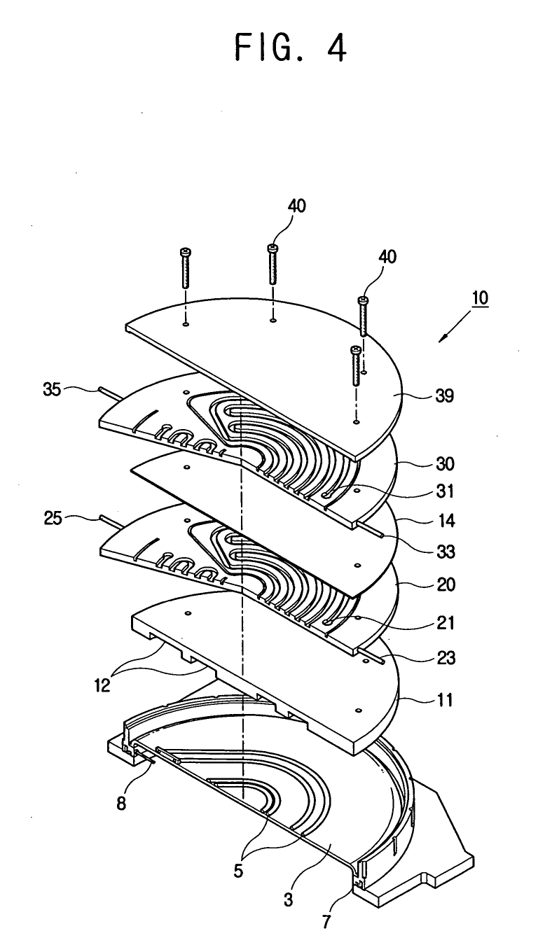

In the embodiments described above, the cooler 20 and the auxiliary cooler 30 may be made of a material with the high thermal conductivity. A thermal conductive member may be provided between the heat transfer unit 11, the cooler 20, the heater 14 and the auxiliary cooler 30 to be in close contact with one another to facilitate the thermal conductivity. The heat transfer unit 11, the cooler 20, the heater 14 and the auxiliary cooler 30 may be connected to the chamber main body 7 or the dome 3 by the screw 40 of FIG. 4, but not limited thereto. Other fasteners may be used to connect the heat transfer unit 11, the cooler 20, the heater 14 and the auxiliary cooler 30 with the chamber main body 7 or the dome 3.

As described above, according to the present invention, the temperature of the dome may be maintained constant within the predetermined reference temperature range if the electrical power with the high voltage is supplied to the antenna to generate the plasma with the high density in the chamber.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A semiconductor manufacturing apparatus comprising:
a chamber main body and a dome to form an accommodating space to accommodate a substrate;
an antenna provided on the dome to generate a plasma from a gas in the accommodating space; and
a temperature controller provided on the dome to control a temperature of the dome, the temperature controller comprising:
a heat transfer unit provided on the dome and the antenna,
a heater provided on the heat transfer unit to heat the dome,
a cooler provided between the heat transfer unit and the heater to cool the dome, and
an adjusting valve connected to the cooler to adjust the quantity of coolant supplied to the cooler to keep the temperature of the dome within a predetermined reference temperature range.

2. The semiconductor manufacturing apparatus according to claim 1, wherein the cooler comprises:
a coolant channel to provide a passage of the coolant;
a supply pipe provided at an entrance of the coolant channel; and
a discharge pipe provided at an exit of the coolant channel, the adjusting valve provided at at least one of the supply pipe and the discharge pipe.

3. The semiconductor manufacturing apparatus according to claim 2, wherein the temperature controller further comprises a temperature sensor to sense the temperature of the dome, and the adjusting valve is closed when the temperature of the dome sensed by the temperature sensor is equal to or less than the predetermined reference temperature range, and is opened when the temperature of the dome is above the predetermined reference temperature range.

4. The semiconductor manufacturing apparatus according to claim 3, wherein the predetermined reference temperature range is between approximately −20° C. and +20° C. with respect to a set reference temperature of the dome.

5. The semiconductor manufacturing apparatus according to claim 1, wherein the adjusting valve is controlled according to an electrical power supplied to the antenna.

6. The semiconductor manufacturing apparatus according to claim 1, further comprising an upper cover formed on the heater.

7. The semiconductor manufacturing apparatus according to claim 1, wherein the temperature controller further comprises an auxiliary cooler provided on the heater to cool the dome.

8. The semiconductor manufacturing apparatus according to claim 7, wherein the auxiliary cooler comprises:
an auxiliary coolant channel to provide a passage of the coolant;
an auxiliary supply pipe provided at an entrance of the auxiliary coolant channel; and
an auxiliary discharge pipe provided at an exit of the auxiliary coolant channel.

9. The semiconductor manufacturing apparatus according to claim 8, wherein the temperature controller further comprises an auxiliary adjusting valve provided at at least one of the auxiliary supply pipe and the auxiliary discharge pipe to adjust the quantity of the coolant supplied to the auxiliary coolant channel.

10. The semiconductor manufacturing apparatus according to claim 9, wherein the auxiliary adjusting valve is controlled according to the temperature of the dome.

11. The semiconductor manufacturing apparatus according to claim 9, wherein the auxiliary adjusting valve is controlled according to an electrical power supplied to the antenna.

12. The semiconductor manufacturing apparatus according to claim 7, wherein the auxiliary temperature controller further comprises a cover provided on the auxiliary cooler to prevent a leakage of coolant from the coolant channel.

13. A semiconductor manufacturing apparatus comprising:
a chamber main body;
a dome to form an accommodating space with the chamber main body;
an antenna disposed on a dome surface opposite to the accommodating space to output a power to the accommodating space through the dome;
a heat transfer unit formed on the dome and the antenna;
a cooler formed on the heat transfer unit to control a temperature of the accommodating space through the heat transfer unit; and
a heater formed on the cooler to heat the dome to generate a heat to control the temperature of the accommodating space of the dome through the heat transfer unit and the cooler.

14. The semiconductor manufacturing apparatus according to claim 13, further comprising:
a cover formed on the heater to prevent a leakage of the heat.

15. The semiconductor manufacturing apparatus according to claim 14, wherein the cooler comprises at least one groove formed on a side of the cooler facing the cover, and the groove forms a coolant channel with the cover to provide a passage of a coolant.

16. The semiconductor manufacturing apparatus according to claim 15, wherein the groove is spaced apart from the heater.

17. The semiconductor manufacturing apparatus according to claim 13, further comprising:
an auxiliary cooler formed on the heater to control the temperature of the accommodating space; and
a cover formed on the auxiliary cooler to prevent a leakage of the heat.

18. The semiconductor manufacturing apparatus according to claim 17, wherein the auxiliary cooler comprises a groove formed on a side of cooler facing the cover, and the groove forms a coolant channel with the cover to provide a passage of a coolant.

19. The semiconductor manufacturing apparatus according to claim 17, wherein the heater is disposed between the cooler and the auxiliary cooler.

20. An apparatus to perform a deposition process, comprising:
a chamber body;
a dome to enclose the change body;
a gas supply unit to provide a gaas with the enclosed chamber body;
a power source procided on the dome to change the gas to a plasma state;
a heat transfer unit provided onteh dome to increase the temperature of the dome to a predetermined temperature;
a heater procided on the heat transfer unit to supply heat to the heat transfer unit; and
a controllable cooler provided between the heat transfer unit and the heater to control the temperature of the dome.

21. The apparatus according to claim 28, further comprising:
an adjusting valve to control an amount of coolant to be applied to the cooller to control the temperature of the dome.

22. The apparatus according to claim 29, wherein the deposition process is performed during manufacturing very large scale integrated (VLSI) electronic components.
